(19) United States
(12) Patent Application Publication
(10) Pub. No.: US 2009/0223932 A1
(43) Pub. Date: Sep. 10, 2009

(54) ELECTRODE UNIT, SUBSTRATE PROCESSING APPARATUS, AND TEMPERATURE CONTROL METHOD FOR ELECTRODE UNIT

(75) Inventors: Tsuyoshi Hida, Nirasaki City (JP); Jun Oyabu, Hwaseong-si (KR)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/397,708

(22) Filed: Mar. 4, 2009

Related U.S. Application Data
(60) Provisional application No. 61/055,521, filed on May 23, 2008.

(30) Foreign Application Priority Data
Mar. 5, 2008 (JP) 2008-054621

(51) Int. Cl. H01L 21/3065

(52) U.S. Cl. 216/67; 156/345.37

(57) ABSTRACT

An electrode unit is disposed in a substrate processing apparatus including a processing chamber for processing a substrate by plasma. The electrode unit includes an electrode layer having a surface exposed to inside of the processing chamber and an opposing surface disposed at the opposite side of the exposed surface, a heating layer and a cooling layer that the electrode layer, the heating layer and the cooling layer are disposed in said order from the processing chamber. The heating layer covers the opposing surface of the electrode layer while the cooling layer covers the opposing surface of the electrode layer via the heating layer, and a heat transfer layer filled up with a heat transfer medium is interposed between the heating layer and the cooling layer.

### FIELD OF THE INVENTION

The present invention relates to an electrode unit, a substrate processing apparatus, and a temperature control method for the electrode unit; and, more particularly, to an electrode unit of a substrate processing apparatus for performing a plasma process on a substrate.

### BACKGROUND OF THE INVENTION

A substrate processing apparatus for performing a plasma process on a semiconductor wafer includes a chamber for accommodating the semiconductor wafer therein; a mounting table disposed in the chamber, for mounting the semiconductor wafer thereon; and a shower head disposed to face the mounting table, for supplying a processing gas into the chamber. The mounting table serves as a lower electrode unit by being connected with a high frequency power supply. The shower head has a circular plate shaped electrode layer and serves as an upper electrode unit. In the substrate processing apparatus, the processing gas in the chamber is excited into a plasma by a high frequency voltage applied between the mounting table and the electrode layer of the shower head.

Here, since distribution in the plasma process result is affected by the temperature of the electrode layer, the temperature of the electrode layer needs to be kept constant during the plasma process. However, the electrode layer of the upper electrode unit suffers a temperature rise due to a heat transfer from the plasma, so that it needs to be cooled.

Therefore, in the conventional substrate processing apparatus, a coolant path is provided to surround the electrode layer, and the electrode layer is cooled by allowing a coolant to flow through the coolant path. Further, since the temperature of the electrode layer may be low at the beginning of the plasma process, the electrode layer also needs to be heated. For this purpose, a heater is disposed to surround and heat the electrode layer in the conventional substrate processing apparatus (see, e.g., Japanese Patent Laid-open Application No. 2005-150606).

Recently, however, a groove width or a hole diameter formed by plasma etching is required to be further miniaturized, and there is a demand for the realization of more uniform distribution in the plasma process result.

In the conventional substrate processing apparatus, however, since the coolant path or the heater is disposed to surround the electrode layer, the temperature may not be controlled appropriately on a central portion of the electrode layer while a temperature control is properly performed on a peripheral portion of the electrode layer. As a result, it becomes difficult to realize the more uniform distribution in the plasma process result inside the chamber.

Further, deposits tend to be adhered to a low-temperature member, however, if the appropriate temperature control of the central portion of the electrode layer fails during the plasma process, then the central portion of the electrode layer may be kept at low temperature. As a result, the deposits can also be attached to the central portion of the electrode layer. The adhered deposits may peel off and become particles during a plasma process of another semiconductor wafer, adhering to the surface thereof.

### SUMMARY OF THE INVENTION

In view of the foregoing, the present invention provides an electrode unit capable of controlling the temperature of the entire region of an electrode layer appropriately, and also provides a substrate processing apparatus and a temperature control method for the electrode unit.

In accordance with a first aspect of the present invention, there is provided an electrode unit disposed in a substrate processing apparatus including a processing chamber for processing a substrate by plasma, including: an electrode layer having a surface exposed to inside of the processing chamber and an opposing surface disposed at the opposite side of the exposed surface; a heating layer; and a cooling layer, wherein the electrode layer, the heating layer and the cooling layer are disposed in said order from the processing chamber, and the heating layer covers the opposing surface of the electrode layer while the cooling layer covers the opposing surface of the electrode layer via the heating layer, and a heat transfer layer filled up with a heat transfer medium is interposed between the heating layer and the cooling layer.

The heating layer may cover the entire opposing surface of the electrode layer while the cooling layer may cover the entire opposing surface of the electrode layer via the heating layer.

With such configuration, since the entire surface of the electrode layer exposed to inside of the processing chamber is covered by the heating layer and also covered by the cooling layer via the heating layer, the electrode layer can be heated and cooled actively over its entire region, whereby the temperature of the electrode layer 32 can be controlled appropriately.

Moreover, if the heating layer and the cooling layer are in direct contact with each other, there is a concern that the heating layer or the cooling layer may be damaged as a result of being rubbed against each other due to a difference in their thermal expansion amounts. In the above configuration, however, since the heat transfer layer filled up with the heat transfer medium is disposed between the heating layer and the cooling layer, the heating layer and the cooling layer does not come into contact with each other, so that their damages can be prevented.

The substrate processing apparatus may include another electrode unit for applying a high frequency voltage into the processing chamber to generate the plasma, and the filled heat transfer medium is exhausted from the heat transfer layer when said another electrode unit stops applying the high frequency voltage.

With such configuration, if the another electrode unit for applying the high frequency voltage into the processing chamber to generate the plasma stops the application of the high frequency voltage, the heat transfer layer exhausts the filled heat transfer medium therefrom. Accordingly, the heat transfer layer serves as a heat insulating layer for blocking a heat transfer from the electrode layer to the cooling layer, so that the electrode layer heated by heat transferred from the plasma can be maintained high. As a result, adherence of deposits to the electrode layer can be prevented.

The heat transfer medium may be a heat transfer gas.

With such configuration, since the heat transfer medium may be a heat transfer gas, the filling/discharging of the heat transfer medium into/from the heat transfer layer can be carried out promptly, resulting in improvement of throughput.

A processing gas for generating the plasma is used as the heat transfer gas.

With such configuration, since the processing gas for generating the plasma is used as the heat transfer gas, an additional installation of a gas line for filling the heat transfer gas becomes unnecessary, so that the configuration of the electrode unit can be simplified.

If the processing gas is used as the heat transfer gas, the heat transfer layer is filled up with the processing gas when the processing gas is supplied into the processing chamber, and the processing gas is exhausted from the heat transfer layer when the processing gas is discharged out of the processing chamber. Typically, as the another electrode unit initiates the application of the high frequency voltage, the processing gas is supplied and as that electrode unit stops the application of the high frequency voltage, the processing gas is exhausted. Therefore, the filling and discharging of the processing gas into and from the heat transfer layer can be synchronized with the start and stop of the application of the high frequency voltage. As a result, the temperature of the electrode unit can be more appropriately controlled.

The electrode unit may supply the processing gas into the processing chamber, and the heat transfer layer may be formed so as to cover the electrode layer except a periphery portion thereof and communicate with the inside of the processing chamber through gas holes, and the processing gas may be supplied into the heat transfer layer.

With such configuration, the heat transfer layer communicating with the processing chamber via the gas holes is formed so as to cover the electrode layer except its peripheral portion. Thus, when filled up with the processing gas, the heat transfer layer transfers heat from the electrode layer to the cooling layer, and the processing gas can be supplied into the processing chamber while diffused over the substantially entire surface of the electrode layer. Thus, more uniform distribution in a plasma process result can be realized.

The heat transfer medium may be a thermally conductive liquid.

With such configuration, since the thermally conductive liquid has a high thermal conductivity, it can carry out the cooling of the electrode layer by the cooling layer effectively.

The heat transfer medium may further be a heat transfer sheet.

With such configuration, since the heat transfer medium may be a heat transfer sheet, it can be handled easily, and an assembly of the electrode unit can be easily carried out.

In accordance with a second aspect of the present invention, there is provided a substrate processing apparatus including: a processing chamber for processing a substrate by plasma; and an electrode unit, wherein the electrode unit includes an electrode layer having a surface exposed to inside of the processing chamber and an opposing surface disposed at the opposite side of the exposed surface, a heating layer and a cooling layer disposed in said order from the processing chamber, and the heating layer covers the opposing surface of the electrode layer while the cooling layer covers the opposing surface of the electrode layer via the heating layer, and a heat transfer layer filled up with a heat transfer medium is interposed between the heating layer and the cooling layer.

The heating layer may cover the entire opposing surface of the electrode layer while the cooling layer may cover the entire opposing surface of the electrode layer via the heating layer.

With such configuration, since the entire surface of the electrode layer exposed to inside of the processing chamber is covered by the heating layer and also covered by the cooling layer via the heating layer, the electrode layer can be heated and cooled actively over its entire region, whereby the temperature of the electrode layer 32 can be controlled appropriately.

Moreover, if the heating layer and the cooling layer are in direct contact with each other, there is a concern that the heating layer or the cooling layer may be damaged as a result of being rubbed against each other due to a difference in their thermal expansion amounts. In the above configuration, however, since the heat transfer layer filled up with the heat transfer medium is disposed between the heating layer and the cooling layer, the heating layer and the cooling layer does not come into contact with each other, so that their damages can be prevented.

In accordance with a third aspect of the present invention, there is provided a temperature control method for an electrode unit disposed in a substrate processing apparatus including a processing chamber for processing a substrate by plasma, wherein the electrode unit includes an electrode layer exposed to inside of the processing chamber, a heating layer and a cooling layer disposed in said order from the processing chamber and a heat transfer layer made up of a space is interposed between the heating layer and the cooling layer, the method including: an electrode layer cooling step of filling the heat transfer layer with a heat transfer medium along with the start of an application of a high frequency voltage by another electrode unit incorporated in the substrate processing apparatus, for applying the high frequency voltage into the processing chamber to generate the plasma; and an electrode layer heat insulating step of exhausting the filled heat transfer medium from the heat transfer layer along with the stop of the application of the high frequency voltage by said another electrode unit.

In accordance with the above-described temperature control method for the electrode unit, the heat transfer medium is filled into the heat transfer layer with the start of the application of the high frequency voltage by the another electrode unit, and the filled heat transfer medium is exhausted from the heat transfer layer along with the stop of the application of the high frequency voltage by the another electrode unit.

Accordingly, while the electrode layer is receiving the heat from the plasma, the heat transfer layer transfers the heat from the electrode layer to the cooling layer, whereby the electrode layer is cooled, and uniform distribution in the plasma process result can be realized. Meanwhile, while heat is not transferred to the electrode layer from the plasma, the heat transfer layer serves as the heat insulating layer which blocks a heat transfer from the electrode layer to the cooling layer.

Thus, the temperature of the electrode layer heated by the heat from the plasma can be maintained high, whereby adherence of deposits to the electrode layer can be prevented.

### BRIEF DESCRIPTION OF THE DRAWINGS

The objects and features of the present invention will become apparent from the following description of embodiments, given in conjunction with the accompanying drawings, in which:

FIG. 1 is a cross sectional view schematically illustrating a configuration of a substrate processing apparatus including an electrode unit in accordance with a first embodiment of the present invention;

FIG. 2 sets forth an enlarged cross sectional view showing a shower head of FIG. 1;

FIGS. 3A to 3D illustrate arrangement of a heating wire constituting a heater embedded in a heating layer of FIG. 1, wherein FIG. 3A shows an example of the heating wire in accordance with the first embodiment of the present invention, and FIGS. 3B to 3D show a first to a third modification example, respectively;

FIG. 4 presents a flowchart to describe a temperature control method for the electrode unit in accordance with the first embodiment of the present invention;

FIG. 5 provides a flowchart to describe a temperature control method for an electrode unit in accordance with a second embodiment of the present invention; and

FIG. 6 is an enlarged cross sectional view illustrating a modification example of a shower head serving as the electrode unit in accordance with the second embodiment of the present invention.

### DETAILED DESCRIPTION OF THE EMBODIMENT

Hereinafter, embodiments of the present invention will be described with reference to the accompanying drawings, which form a part hereof.

First, an electrode unit in accordance with a first embodiment of the present invention will be explained.

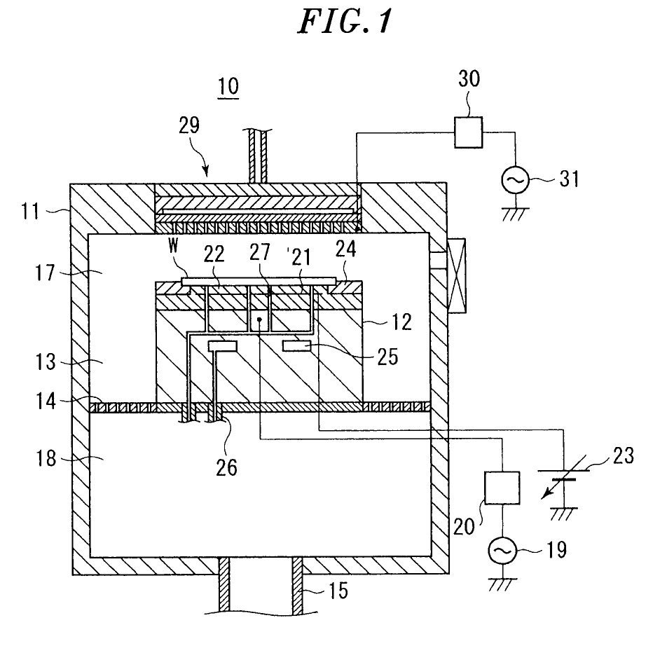

FIG. 1 is a cross sectional view of a substrate processing apparatus including the electrode unit in accordance with the first embodiment of the present invention.

As illustrated in FIG. 1, the substrate processing apparatus 10 includes a chamber 11 for accommodating therein a semiconductor wafer W having a diameter of about 300 mm (hereinafter referred to as a “wafer”), and a columnar susceptor 12 (another electrode unit) for mounting the wafer W thereon is disposed in the chamber 11. Further, the substrate processing apparatus 10 is also provided with a side exhaust path 13 formed by the inner sidewall of the chamber 11 and the lateral surface of the susceptor 12 to be used as a flow path for exhausting a gas above the susceptor 12 out of the chamber 11. An exhaust plate 14 is disposed on the side exhaust path 13.

The exhaust plate 14 is a plate-shaped member provided with a number of openings, and it serves as a partition plate for partitioning the chamber 11 into an upper region and a lower region. Plasma is generated in the upper region (hereinafter referred to as a “processing chamber”) 17 of the chamber 11 partitioned by the exhaust plate 14. Further, connected to the lower region 18 (hereinafter referred to as a “gas exhaust chamber (manifold)) of the chamber 11 is a gas exhaust pipe 15 for exhausting the gas from the chamber 11. The exhaust plate 14 captures or reflects the plasma generated in the processing chamber 17, thus preventing leakage of the plasma into the manifold 18.

The gas exhaust pipe 15 is connected with a TMP (Turbo Molecular Pump) and a DP (Dry Pump) (none of which are shown), and these pumps depressurize the inside of the chamber 11 by evacuating the chamber to vacuum. More specifically, the DP depressurizes the inside of the chamber 11 from an atmospheric pressure into a medium vacuum state of a pressure level (e.g., about 1.3×10 Pa (0.1 Torr) or less), and the TMP depressurizes the inside of the chamber 11 into a high vacuum state of a pressure level (e.g., about 1.3×10⁻³ Pa (1.0×10⁻⁵ Torr)) lower than that of the medium vacuum state in cooperation with the DP. Further, the internal pressure of the chamber 11 is controlled by an APC valve (not shown).

A lower electrode high frequency power supply 19 is connected to the susceptor 12 inside the chamber 11 via a lower matching unit 20. The lower electrode high frequency power supply 19 supplies a preset high frequency power to the susceptor 1, whereby the susceptor 12 serves as a lower electrode unit for applying a high frequency voltage into the processing chamber 17. Further, the lower matching unit 20 serves to reduce reflection of the high frequency power from the susceptor 12 to thereby maximize the efficiency of the high frequency power supply to the susceptor 12.

An electrostatic chuck 22 having an electrostatic electrode plate 21 therein is provided on top of the susceptor 12. The electrostatic electrode plate 21 is made of ceramic and has a configuration in which an upper circular plate-shaped member having a diameter smaller than that of a lower circular plate-shaped member is placed on top of the lower circular plate-shaped member. When the wafer W is mounted on the susceptor 12, the wafer W is placed on the upper circular plate-shaped member of the electrostatic chuck 22.

Further, a DC power supply 23 is electrically connected with the electrostatic electrode plate 21 of the electrostatic chuck 22. If a high positive DC voltage is applied to the electrostatic electrode plate 21, a negative potential is generated on the wafer W's surface in contact with the electrostatic chuck 22 (hereinafter, referred to as a “rear surface”), so that a potential difference is generated between the electrostatic electrode plate 21 and the rear surface of the wafer W, and the wafer W is attracted to and held on the upper circular plate-shaped member of the electrostatic chuck 22 by a Coulomb force or a Johnsen-Rahbek force generated due to the potential difference.

Further, a circular ring-shaped focus ring 24 is disposed on the electrostatic chuck 22 to surround the wafer W held thereon. The focus ring 24 is made of a conductive member, e.g., silicon, and serves to concentrate the plasma inside the processing chamber 17 toward the surface of the wafer W, thus improving the efficiency of plasma etching.

Further, an annular coolant path 25 extended in, for example, a circumferential direction is provided inside the susceptor 12. A low-temperature coolant, e.g., cooling water or Galden (registered trademark) is circulated into the coolant path 25 from a chiller unit (not shown) via a coolant line 26. The susceptor 12 cooled by the low-temperature coolant cools down in turn the wafer W and the focus ring 24 via the electrostatic chuck 22.

As for the electrostatic chuck 22, heat transfer gas supply holes 27 are opened in the upper circular plate-shaped member's top surface portion on which the wafer W is attracted and held (hereinafter, referred to as an “attracting surface”). A helium (He) gas as a heat transfer gas is supplied into a gap between the attracting surface and the rear surface of the wafer W via the heat transfer gas supply holes 27. The helium gas, which is supplied into the gap, transfers heat of the wafer W to the electrostatic chuck 22 effectively.

A shower head (electrode unit) 29 is disposed at a ceiling portion of the chamber 11 to face the susceptor 12. The shower head 29 is connected with an upper electrode high frequency power supply 31 via an upper matching unit 30. As the upper electrode high frequency power supply 31 supplies a preset high frequency power to the shower head 29, the shower head 29 serves as an upper electrode unit for applying a high frequency voltage to the inside of the processing chamber 17. Further, the upper matching unit 30 has the same function as that of the lower matching unit 20 explained above.

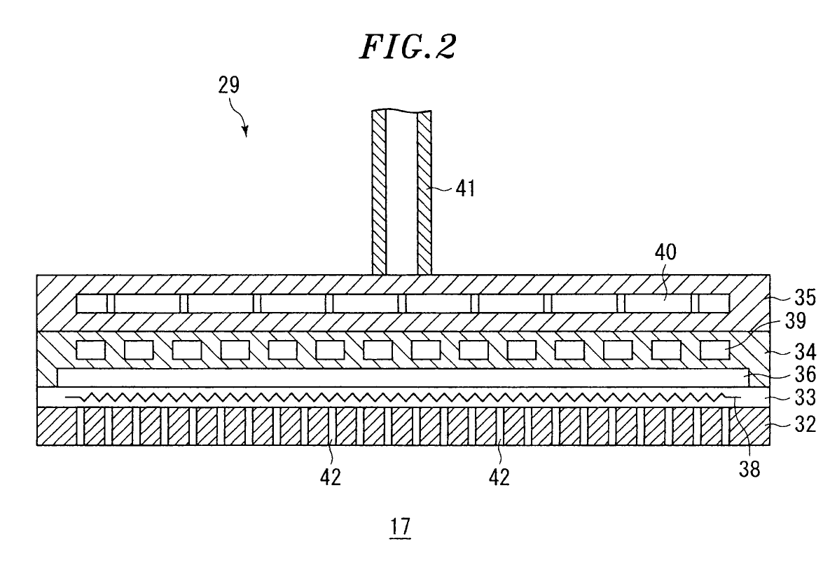

FIG. 2 is an enlarged cross sectional view illustrating the shower head shown in FIG. 1.

As shown in FIG. 2, the shower head 29 includes a circular plate-shaped electrode layer 32 made of a conductor, e.g., aluminum; a circular plate-shaped heating layer 33 made of an insulator, e.g., ceramic; a circular plate-shaped cooling layer 34 made of a conductor coated with an insulating film, e.g., alumite-coated aluminum; and a support 35. The electrode layer 32 is exposed inside the processing chamber 17, and the electrode layer 32, the heating layer 33 and the cooling layer 34 are arranged in this order from the processing chamber 17. The electrode layer 32, the heating layer 33 and the cooling layer 34 are supported by the support 35.

Since the diameters of the heating layer 33 and the cooling layer 34 are equal to the diameter of the electrode layer 33, the heating layer 33 covers the entire surface of the electrode layer 32, and the cooling layer 34 also covers the entire surface of the electrode layer 32 via the heating layer 33. However, the diameters of the heating layer 33 or the cooling layer 34 need not be identical with that of the electrode layer 32, but it may be also possible to set the diameter of the heating layer 33 or the cooling layer 34 to be larger than the diameter of the electrode layer 32. Even in such case, the entire surface of the electrode layer 32 can also be covered by the heating layer 33 or the cooling layer 34.

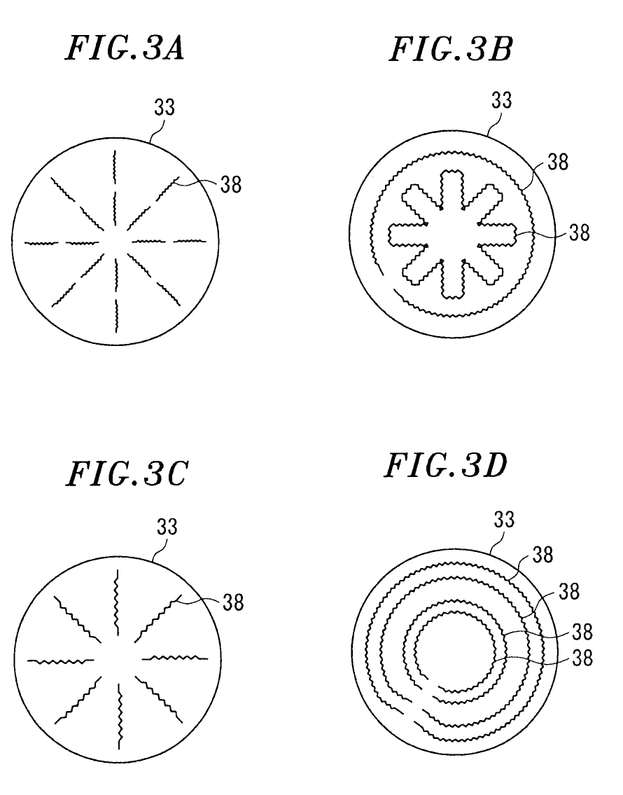

A heater made up of a heating wire 38 is embedded in the heating layer 33. The heating wire 38 constituting the heater is installed throughout the entire heating layer 33, as shown in FIGS. 3A to 3D, for example. As a result, the heating layer 33 is allowed to emit heat from its entire surface by the heater, thereby heating the entire region of the electrode layer 32.

Embedded in the cooling layer 34 is a cooling channel 39 through which a cooling medium flows. The cooling channel 39 is installed throughout the entire region of the cooling layer 34. As a result, the cooling layer 34 absorbs heat from its entire surface through the cooling channel 39, thereby cooling the entire region of the electrode layer 32.

In the shower head 29, the electrode layer 32 has a temperature sensor (not shown), and the heat emission rate of the heating layer 33 or the heat absorption rate of the cooling layer 34 is controlled based on a measurement result of the temperature sensor, whereby the temperature of the electrode layer 32 is controlled.

Furthermore, the shower head 29 also has a heat transfer layer 36 formed in a circular plate-shaped space interposed between the heating layer 33 and the cooling layer 34. The heat transfer layer 36 is filled up with a heat transfer gas, e.g., a helium gas, which is used as a heat transfer medium. The heat transfer gas is filled up by an external heat transfer gas supply unit (not shown), and the heat transfer gas filled in the heat transfer layer 36 is exhausted by an external heat transfer gas exhaust unit (not shown).

Since the heat transfer layer 36 transfers heat when it is filled with the heat transfer gas, the cooling layer 34 can absorb the heat of the electrode layer 32 via the heat transfer layer 36 and the heating layer 33, thereby cooling the electrode layer 32. Meanwhile, when the heat transfer gas is exhausted from the heat transfer layer 36, the heat transfer layer 36 does not transfer the heat any more, so that the cooling layer 34 cannot absorb the heat of the electrode layer 32, and cooling of the electrode layer 32 does not progress. That is, the temperature of the electrode layer 32 can be controlled by performing the filling/discharging of the transfer gas into/from the heat transfer layer 36. Especially, when the electrode layer 32 does not receive heat from the plasma and the heating layer 33 does not emit heat, the temperature of the electrode layer 32 can be maintained high (e.g., about 200° C.) by means of exhausting the heat transfer gas.

Furthermore, since the heat transfer gas has a high diffusion property, it is distributed over the entire region inside the heat transfer layer 36. In addition, since the heat transfer gas comes into contact with the surface of the heating layer 33 or the cooling layer 34 in a uniform manner regardless of the surface state of the heating layer 33 or the cooling layer 34 exposed to the heat transfer layer 36, the heat transfer layer 36 exhibits a substantially same level of heat transfer efficiency over the entire region thereof.

Meanwhile, when the temperature control of the electrode layer 32 is performed, the heating layer 33 is expanded, while the cooling layer 34 is contracted. As a result, if the heating layer 33 and the cooling layer 34 are configured so as to be in direct contact with each other, a difference in their thermal expansion amounts is large, so that the heating layer 33 and the cooling layer 34 is highly likely to be relatively moved and rubbed against each other.

As a solution to the corresponding problem, the shower head 29 includes the above-described heat transfer layer 36. Since the heat transfer layer 36 is interposed between the heating layer 33 and the cooling layer 34 in the shower head 29, the heating layer 33 and the cooling layer 34 are prevented from coming into direct contact with each other.

The support 35 has a buffer chamber 40 therein, and a processing gas inlet pipe 41 is connected to the buffer chamber 40. The buffer chamber 40 communicates with the processing chamber 17 via gas holes (not shown) provided in the heating layer 33 and the cooling layer 34 and gas holes 42 provided in the electrode layer 32. The shower head 29 supplies the processing gas, which is introduced to the buffer chamber 40 from the processing gas inlet pipe 41, into the processing chamber 17 through the gas holes 42 and the like.

In this substrate processing apparatus 10, by applying the high frequency voltage to the inside of the processing chamber 17 by supplying the high frequency powers to the susceptor 12 and the shower head 29, the processing gas supplied from the shower had 29 into the processing chamber 17 is excited into high-density plasma, so that plasma etching is performed on the wafer W.

An operation of each component of the above-described substrate processing apparatus 10 is controlled by a CPU of a controller (not shown) included in the substrate processing apparatus 10.

With the shower head 29 serving as the electrode unit in accordance with the present embodiment, since the entire surface of the electrode layer 32 exposed in the processing chamber 17 is covered by the heating layer 33 and also covered by the cooling layer 34 via the heating layer 33, the electrode layer 32 can be heated and cooled actively over its entire region, whereby the temperature of the electrode layer 32 can be controlled appropriately. Therefore, during the plasma etching, uniform distribution in a plasma process result can be realized in the chamber 11 and attachment of deposits to a central portion of the electrode layer 32 can be prevented.

Furthermore, since the heat transfer layer 36 that the heat transfer gas is filled up is present between the heating layer 33 and the cooling layer 34 in the shower head 29, the heating layer 33 and the cooling layer 34 do not come into direct contact with each other, so that they are prevented from being rubbed against each other due to the difference in the their thermal expansion amounts. As a result, damage of the heating layer 33 or the cooling layer 34 can be prevented.

Moreover, in shower head 29, since the heat transfer gas is used as the heat transfer medium filled in the heat transfer layer 36, the filling/discharging of the heat transfer medium in/out of the heat transfer layer 36 can be carried out promptly, resulting in improvement of throughput.

Now, a temperature control method for the electrode unit in accordance with the embodiment of the present invention will be described.

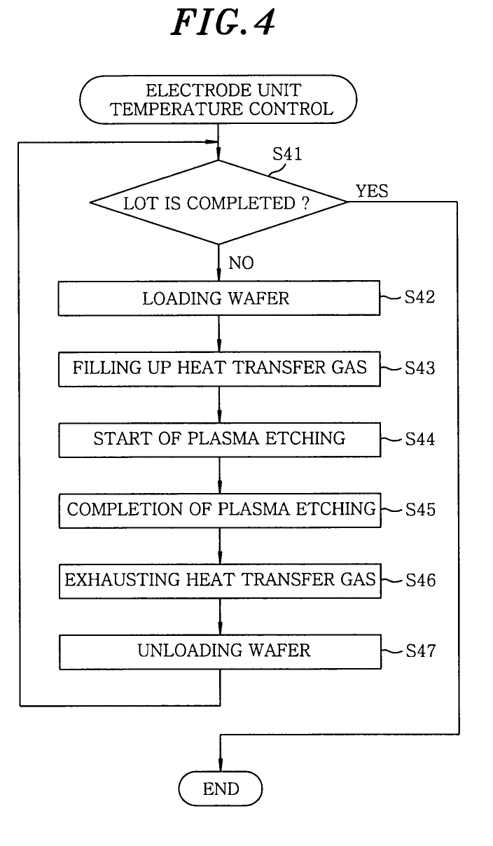

FIG. 4 provides a flowchart to describe the temperature control method for the electrode unit in accordance with the embodiment of the present invention.

First, the CPU of the substrate processing apparatus 10 determines whether plasma etching of one lot of wafers W is completed (step S41). If so, the process is completed, and if the plasma etching of one lot of wafers W is not completed, a wafer W is loaded into the chamber 11 and mounted on the susceptor 12 (step S42).

Next, the shower head 29 supplies the processing gas into the processing chamber 17, and the heat transfer gas supply unit fills the heat transfer gas to the heat transfer layer 36 (step S43) (electrode layer cooling step). Then, a high frequency voltage is applied to the inside of the processing chamber 17 via the susceptor 12 and the shower head 29, whereby plasma is generated from the processing gas, and plasma etching of the wafer W is begun (step S44). While the plasma etching is continued over a predetermined period afterwards the cooling layer 34 can cool down the electrode layer 32 via the heat transfer layer 36 and the heating layer 33. Thus, it is possible to control the temperature of the electrode layer 32 by means of the heating layer 33 and the cooling layer 34 based on a measurement result of the temperature sensor.

Subsequently, after the plasma etching for a predetermined period of time, the susceptor 12 and the shower head 29 stops applying the high frequency voltage to the inside of the processing chamber 17, and the plasma etching is completed (step S45). Then, the gas exhaust line 15 exhausts the residual processing gas from the processing chamber 17 via the manifold 18, and the heat transfer gas exhaust unit exhausts the filled heat transfer gas from the heat transfer layer 36 (step S46) (electrode layer heat insulating step). Through this step, the cooling layer 34 no more cools the electrode layer 32, and the electrode layer 32 can be maintained at a high temperature.

Thereafter, the wafer W which has undergone the plasma etching is unloaded from the chamber 11 (step S47), and the process returns to the step S41.

Further, in the temperature control method described in FIG. 4, although the application of the high frequency voltage is begun after filling the heat transfer layer 36 with the heat transfer gas and the heat transfer gas is exhausted from the heat transfer layer 36 after stopping the application of the high frequency voltage, it may be also possible to initiate the application of the high frequency voltage prior to filling the heat transfer layer 36 with the heat transfer gas, or to exhaust the heat transfer gas from the heat transfer layer 36 before stopping the application of the high frequency voltage.

With the electrode unit temperature control method of FIG. 4, the heat transfer gas is filled in the heat transfer layer 36 along with the start of the application of the high frequency voltage by the susceptor 12 and the shower head 29, and the filled heat transfer gas is exhausted from the heat transfer layer 36 along with the stop of the application of the high frequency voltage by the susceptor 12 and the shower head 29. Accordingly, while the electrode layer 32 is receiving heat from the plasma, the heat transfer layer 36 transfers the heat from the electrode layer 32 to the cooling layer 34, whereby the electrode layer 32 is cooled, and uniform distribution in the plasma process result can be realized.

Meanwhile, when heat is no more transferred to the electrode layer 32 from the plasma, the heat transfer layer 36 serves as a heat insulating layer so that a heat transfer is blocked from the electrode layer 32 to the cooling layer 34. Thus, the temperature of the electrode layer 32 heated by the heat from the plasma can be maintained high, whereby adherence of deposits to the electrode layer 32 can be prevented.

Now, an electrode unit in accordance with a second embodiment of the present invention will be explained.

Since the configuration and function of the present embodiment are basically identical with those of the first embodiment, description of redundant configuration and function will be omitted, while distinctive parts are elaborated.

In a shower head 29 as the electrode unit in accordance with the second embodiment, not a heat transfer gas but a processing gas is filled in a heat transfer layer 36. Further, the substrate processing unit 10 includes neither a heat transfer gas supply unit nor a heat transfer gas exhaust unit. Instead, a processing gas inlet pipe 41 is connected to the heat transfer layer 36, and the heat transfer layer 36 is allowed to communicate with a manifold 18 via an opening/closing valve (not shown). Here, since the processing gas has some degree of thermal conductivity as well, the heat transfer layer 36 serves to transfer heat while it is filled with the processing gas, whereby the cooling of the electrode layer 32 by the heat transfer layer 36 can be carried out.

In the shower head 29 in accordance with the present embodiment, additional installation of a gas line to fill the heat transfer gas is not necessary, so that the configuration of the shower head 29 can be simplified.

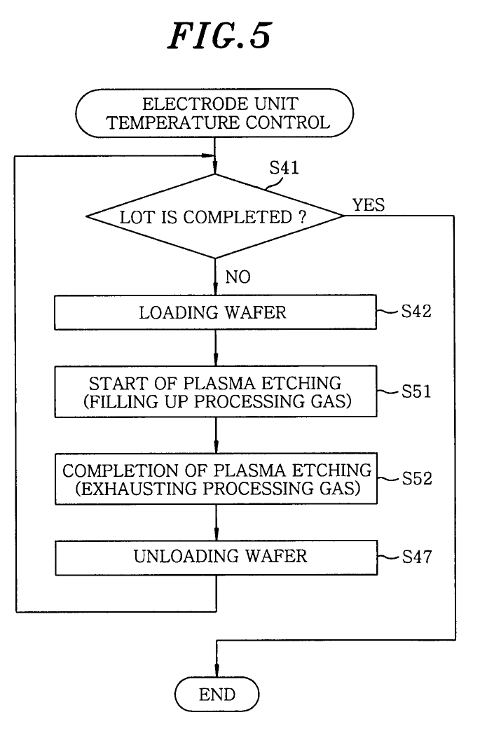

FIG. 5 presents a flowchart to describe a temperature control method for the electrode unit in accordance with the second embodiment of the present invention.

First, after performing the steps S41 and S42 of FIG. 4, the shower head 29 supplies the processing gas into the processing chamber 17, and a high frequency voltage is applied to the inside of the processing chamber 17 via the susceptor 12 and the shower head 29, whereby plasma is generated from the processing gas, and plasma etching of the wafer W is begun. At this time, since the processing gas inlet pipe 41 supplies the processing gas into the heat transfer layer 36 as well as the buffer chamber 40, the heat transfer layer 36 is filled up with the processing gas (step S51), and it can transfer heat.

Subsequently, after the lapse of a predetermined period of plasma etching, the susceptor 12 and the shower head 29 stops applying the high frequency voltage to the inside of the processing chamber 17, and the plasma etching is completed, and the gas exhaust line 15 exhausts the residual processing gas from the processing chamber 17 via the manifold 18 (step S52). At this time, the above-mentioned opening/closing valve is opened, so that the processing gas filled in the heat transfer layer 36 is exhausted via the manifold 18. Afterwards, the heat transfer layer 36 serves as a heat insulating layer.

Thereafter, the wafer W which has undergone the plasma etching is unloaded from the chamber 11 (step S47), and the process returns to the step S41.

With the electrode unit temperature control method of FIG. 5, the heat transfer layer 36 is filled up with the processing gas when the processing gas is supplied into the processing chamber 17, and the processing gas is exhausted from the heat transfer layer 36 when the processing gas in the processing chamber 17 is exhausted. Accordingly, the feeding and discharging of the processing gas into and from the heat transfer layer 36 can be synchronized with the start and stop of the application of the high frequency voltage, and the temperature of the electrode layer 32 can be controlled more appropriately.

In the shower head 29 in accordance with the second embodiment, although the support 35 has the buffer chamber 40 as a processing gas inlet chamber separate from the heat transfer layer 36, the heat transfer layer 36 and the buffer chamber 40 may be integrated as a single body. In this way, the configuration of the shower head 29 can be simplified.

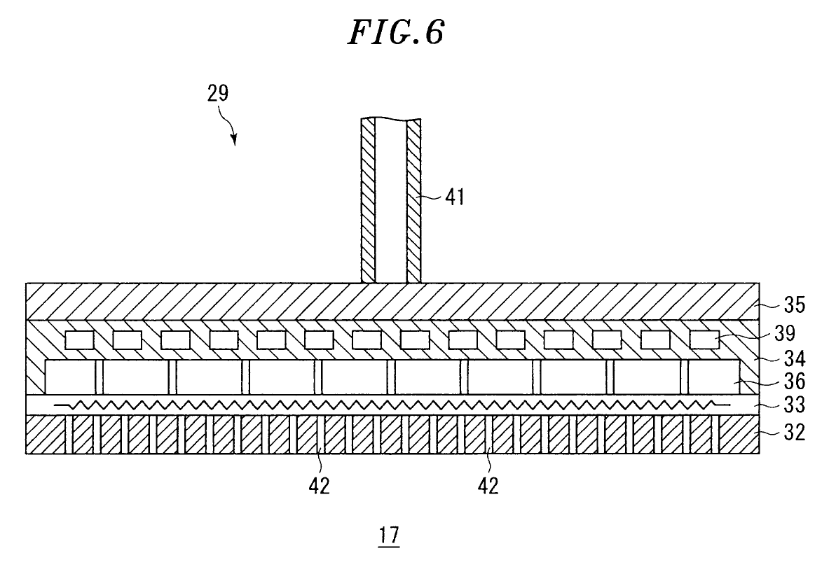

Further, in such case, the buffer chamber 40 of the support 35 is eliminated, and the heat transfer layer 36 is made to communicate with the processing chamber 17 via a plurality of gas holes (the gas holes of the heating layer 33 (not shown) and the gas holes 42), as illustrated in FIG. 6. Further, it is configured such that the heat transfer layer 36 covers the electrode layer 32 except its peripheral portion by setting the diameter of the heat transfer layer 36 to be smaller than the diameter of the electrode layer 32.

With such configuration, when filled up with the processing gas, the heat transfer layer 36 transfers heat from the electrode layer 32 to the cooling layer 34, and the processing gas can be supplied into the processing chamber 17 while diffused over the substantially entire surface of the electrode layer 32. Thus, more uniform distribution in a plasma process result can be realized.

In the above-described embodiments of the present invention, although the heat transfer layer 36 is filled up with the gas (heat transfer gas or the processing gas) as the heat transfer medium, a thermally conductive liquid, e.g., a gel type material or a heat transfer sheet may be employed as the heat transfer medium. Since the thermally conductive liquid has thermal conductivity higher than that of the heat transfer gas in general, it can carry out the cooling of the electrode layer 32 by the cooling layer 34 effectively. Furthermore, since the heat transfer sheet can be handled easily, the assembly of the shower head 29 or the like can be carried out easily.

Although the above-described shower head 29 is applied to the substrate processing apparatus 10 for performing the etching process on the semiconductor wafer, a shower head having the same configuration as that of the shower head 29 can also be applied to a substrate processing apparatus for performing a plasma process on a glass substrate such as a LCD (Liquid Crystal Display), a FPD (Flat Panel Display), or the like.

While the invention has been shown and described with respect to the embodiments, it will be understood by those skilled in the art that various changes and modifications may be made without departing from the scope of the invention as defined in the following claims.

What is claimed is:

1. An electrode unit disposed in a substrate processing apparatus including a processing chamber for processing a substrate by plasma, comprising:
an electrode layer having a surface exposed to inside of the processing chamber and an opposing surface disposed at the opposite side of the exposed surface;
a heating layer; and
a cooling layer,
wherein the electrode layer, the heating layer and the cooling layer are disposed in said order from the processing chamber, and the heating layer covers the opposing surface of the electrode layer while the cooling layer covers the opposing surface of the electrode layer via the heating layer, and a heat transfer layer filled up with a heat transfer medium is interposed between the heating layer and the cooling layer.

2. The electrode unit of claim 1, wherein the heating layer covers the entire opposing surface of the electrode layer while the cooling layer covers the entire opposing surface of the electrode layer via the heating layer.

3. The electrode unit of claim 1, wherein the substrate processing apparatus includes another electrode unit for applying a high frequency voltage into the processing chamber to generate the plasma, and the filled heat transfer medium is exhausted from the heat transfer layer when said another electrode unit stops applying the high frequency voltage.

4. The electrode unit of claim 1, wherein the heat transfer medium is a heat transfer gas.

5. The electrode unit of claim 4, wherein a processing gas for generating the plasma is used as the heat transfer gas.

6. The electrode unit of claim 5, wherein the electrode unit supplies the processing gas into the processing chamber, and the heat transfer layer is formed so as to cover the electrode layer except a periphery portion thereof and communicate with the inside of the processing chamber through gas holes, and the processing gas is supplied into the heat transfer layer.

7. The electrode unit of claim 1, wherein the heat transfer medium is a thermally conductive liquid.

8. The electrode unit of claim 1, wherein the heat transfer medium is a heat transfer sheet.

9. A substrate processing apparatus comprising:
a processing chamber for processing a substrate by plasma; and
an electrode unit,
wherein the electrode unit includes an electrode layer having a surface exposed to inside of the processing chamber and an opposing surface disposed at the opposite side of the exposed surface, a heating layer and a cooling layer disposed in said order from the processing chamber, and the heating layer covers the opposing surface of the electrode layer while the cooling layer covers the opposing surface of the electrode layer via the heating layer, and a heat transfer layer filled up with a heat transfer medium is interposed between the heating layer and the cooling layer.

10. The substrate processing apparatus of claim 9, wherein the heating layer covers the entire opposing surface of the electrode layer while the cooling layer covers the entire opposing surface of the electrode layer via the heating layer.

11. A temperature control method for an electrode unit disposed in a substrate processing apparatus including a processing chamber for processing a substrate by plasma, wherein the electrode unit includes an electrode layer exposed to inside of the processing chamber, a heating layer and a cooling layer disposed in said order from the processing chamber and a heat transfer layer made up of a space is interposed between the heating layer and the cooling layer, the method comprising:
an electrode layer cooling step of filling the heat transfer layer with a heat transfer medium along with the start of an application of a high frequency voltage by another electrode unit incorporated in the substrate processing apparatus, for applying the high frequency voltage into the processing chamber to generate the plasma; and
an electrode layer heat insulating step of exhausting the filled heat transfer medium from the heat transfer layer along with the stop of the application of the high frequency voltage by said another electrode unit.
